(19) United States
(12) Patent Application Publication
(10) Pub. No.: US 2026/0180588 A1
(43) Pub. Date: Jun. 25, 2026

(54) VOLTAGE-TO-FREQUENCY SWITCHING IMPLEMENTATION FOR INCREASED DATACENTER QUALITY

(71) Applicant: NVIDIA Corp., Santa Clara, CA (US)

(72) Inventors: Kevin Wilder, Wilmette, IL (US); Badarish Colathur Arvind, San Jose, CA (US); Jinal Shah, Foster City, CA (US)

(73) Assignee: NVIDIA Corp., Santa Clara, CA (US)

(21) Appl. No.: 19/008,447

(22) Filed: Jan. 2, 2025

Related U.S. Application Data
(63) Continuation-in-part of application No. 18/991,505, filed on Dec. 21, 2024.

(51) Int. Cl. H03L 7/099; H03L 7/08

(52) U.S. Cl. CPC H03L 7/0991; H03L 7/0802

(57) ABSTRACT

Voltage-Frequency domain switching circuits that include multiple stages each configured to receive a throttle code, each of the stages providing a first fast-propagation path for the throttle code to a digitally controlled oscillator, and a frequency locked loop configured to (a) generate a code to the digitally controlled oscillator over a slow path, and (2) disable the fast path to the digitally controlled oscillator upon the code satisfying a match with the throttle code. A second fast-propagation path is configured to propagate a second code to the digitally controlled oscillator.

### CROSS REFERENCE TO RELATED APPLICATIONS

This application claims priority and benefit as a continuation-in-part of application Ser. No. 18/991,505, “Voltage-To-Frequency Switching Implementation for Increased Datacenter Quality”, filed on Dec. 21, 2024, the contents of which are incorporated herein by reference in their entirety.

### BACKGROUND

Voltage-to-Frequency (V-F) switching in an integrated circuit is a technique whereby the frequency of a periodic signal is adjusted to mitigate fluctuations in a voltage, for example a supply voltage of components of the integrated circuit. The relationship between the voltage setting and the corresponding frequency may be referred to as a “V-F curve”.

The performance and power efficiency of different integrated circuits in a computer system may benefit from utilizing different V-F curves tailored to their function. For example, in a computer system utilized in a data center, the graphics processing units and the central processing units may be configured with different V-F curves to improve overall performance and reliability of the computer system.

Some systems may implement multiple V-F switching domains. The V-F switching domains may share a common full-swing voltage interval (VDD-VSS) but may comprise different maximum operating frequencies for the circuitry in those domains.

Different types of instructions executed by a data processor may have different utilization power profiles leading to different maximum frequencies at which the instructions may be executed. For example, in some data processors a half-matrix multiplication and accumulation instruction may comprise a different maximum clock frequency for execution than do other matrix multiply and accumulate instructions. It may therefore be advantageous to group instructions into different V-F curve domains.

Some conventional approaches to V-F switching may require increased post-silicon characterization and pessimistic feature productization margins due to their complexity. These complications may be amplified as the number of V-F switching domains of an integrated circuit increases.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 and FIG. 2 depict aspects of a conventional V-F switching circuit.

FIG. 3 and FIG. 4 depict aspects of an embodiment of a V-F switching circuit.

FIG. 5 depicts an example of transitions to and from a throttled V-F switching domain.

FIG. 6 depict aspects of an embodiment of a V-F switching circuit.

FIG. 7 depicts an example of transitions to and from a throttled V-F switching domain.

FIG. 8 depicts an integrated circuit in accordance with one embodiment.

FIG. 9 depicts an exemplary data center 900, in accordance with at least one embodiment.

### DETAILED DESCRIPTION

Disclosed herein are robust V-F switching mechanisms that reduce transient performance loss and may decrease post-silicon characterization time for integrated circuits. The disclosed mechanisms may be resilient at V-F process corners and may scale to greater numbers of V-F switching domains without a commensurate increase in integrated circuit area.

Exemplary circuits may described herein in terms of ‘positive logic’, meaning that signals are described as ‘asserted’ in a high digital state (e.g., digital ‘1’), and de-asserted in a low digital state (e.g., digital ‘0’). Circuits utilizing ‘negative logic’ (de-asserted as ‘1’ or asserted as ‘0’) or combinations of positive and negative logic may also be readily utilized to implement the disclosed mechanisms.

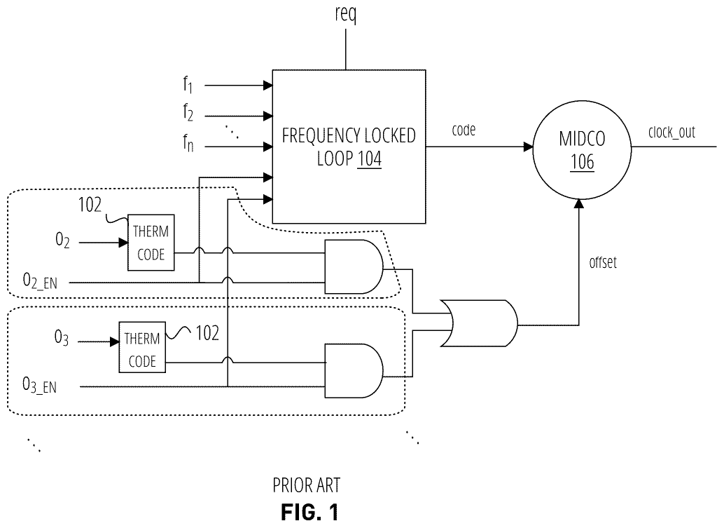

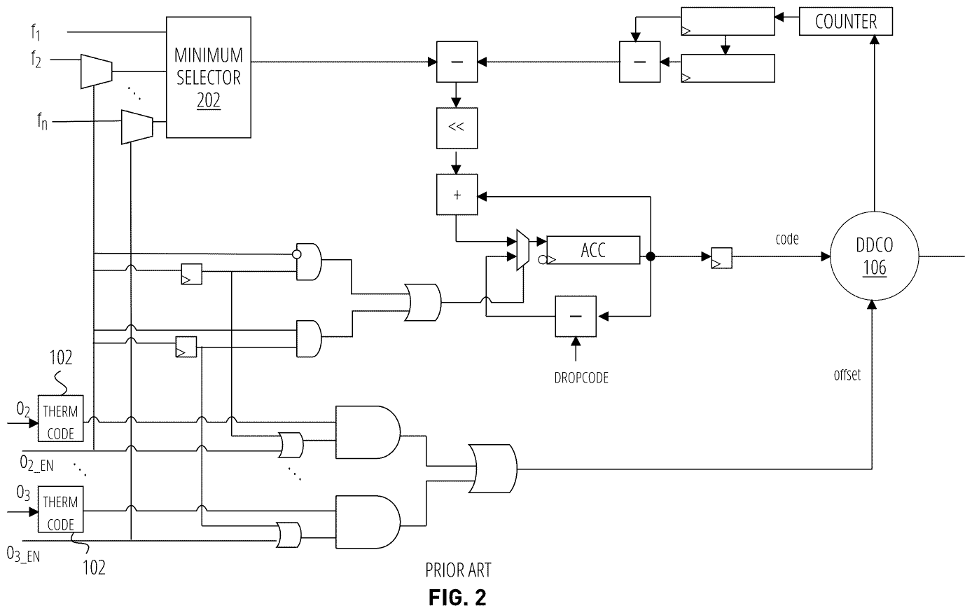

FIG. 1 and FIG. 2 depict aspects of a conventional V-F switching circuit. The circuit comprises a plurality of offset-generation stages (dotted lines) each comprising a thermometer decoder 102 and some combinatorial gates. The circuit further comprises a frequency locked loop 104 and a multiple-input digitally-controlled oscillator 106. The V-F switching circuit may be utilized to respond quickly to transient changes in load voltage, current, or induced noise in an integrated circuit.

A Multiple Input Digitally-Controlled Oscillator (MIDCO) circuit 106 is a type of oscillator for which the output frequency is controllable using multiple digital inputs. Unlike dynamically-controllable oscillators that utilize a single-ended input voltage such as Voltage-Controlled Oscillators (VCOs) and Digitally-Controlled Oscillators (DCOs), MIDCos utilize (at least) a pair of digital inputs to improve noise rejection and enhance stability and linearity. Internally, a MIDCO may be implemented utilizing a Digitally Controlled Oscillator (DCO), a Differential Voltage-Controlled Oscillator (DVCO), and/or a Voltage Controlled Oscillator (VCO) in some embodiments.

The V-F switching circuit may be configured to receive multiple V-F switching domain signals f₁, f₂, etc. These are depicted in FIG. 1 as discrete inputs, one or more of which may be selected at a time by operating a switch (not depicted) internal to the frequency locked loop 104. Alternatively an external switch may be utilized. The frequency locked loop 104 may comprise a minimum selector 202 that propagates the lowest input to its output. The minimum selector 202 may be implemented in manners known in the art.

The frequency locked loop 104 may comprise various logic that is depicted in FIG. 2 with familiar functional symbols such as subtraction circuits (“−”), addition circuits (“+”), accumulators (ACC), flops (boxes comprising a triangular clock input), muxes (truncated triangle), shift circuits (“<<”), and so on.

One of the V-F switching domain signals (e.g., f₁) may be a default setting to apply when none of the operation- or instruction-specific V-F switching domains (f₂, f₃ . . . ) are activated. The req input operates as a selection signal for the V-F switching domain signal(s) to apply to the frequency locked loop 104 at a given point during operation of the integrated circuit.

The settling time of output code of the frequency locked loop 104 in response to a switch to a different V-F switching domain may be unacceptably long. The control signal code thus arrives at the multiple-input digitally-controlled oscillator 106 over a ‘slow-propagation path’. To provide a faster response time to a V-F switch, offset codes O₂, O₃, . . . that effectuate the throttle to output clock signal CLOCK_OUT may be enabled (via signals O_{1_EN}, O_{2_EN} . . . ). The offset codes propagate more quickly (over a ‘fast-propagation path’, i.e., over a path with lower propagation delay) than the time it takes to generate and apply code to the multiple-input digitally-controlled oscillator 106. The offset codes are converted to thermometer codes that are applied directly to the multiple-input digitally-controlled oscillator 106 through low-latency combinatorial logic (e.g., AND and OR gates).

During a transition back to a non-throttled frequency, e.g., f₂→f₁, the frequency locked loop 104 output frequency drops by DROPCODE, offset O₂ is disabled, and the frequency locked loop 104 transitions back to a lock on the default (un-throttled) frequency f₁. The signal O₂ is asserted throughout the duration of slow-down to f₂, thus requiring the application of DROPCODE to prevent frequency overshoot during the reverse transition f₁→f₂. The storage of a DROPCODE incurs additional area on the integrated circuit for each V-F switching domain that is implemented, and the utilization of DROPCODEs may also incur the need for greater timing margins and performance loss.

Due to the combination of the frequency locked loop 104 code and the offset code at the multiple-input digitally-controlled oscillator 106, the conventional V-F switching circuit depicted in FIG. 1 may generate dithering in CLOCK_OUT. The offset codes to apply for particular V-F switching domains may be difficult to characterize, configure, and time properly relative to frequency locked loop 104 output code. Characterization and margining of the circuit in FIG. 1 may also be complicated by cumulative margining. For example, a transition from V-F switching state A to V-F switching state C and from V-F switching state B to V-F switching state C might need to be characterized and margined for the worst of both. In other words, V-F switching state A->V-F switching state B would need a design margin, and V-F switching state B→V-F switching state C might require margin on top of A->B's margin.

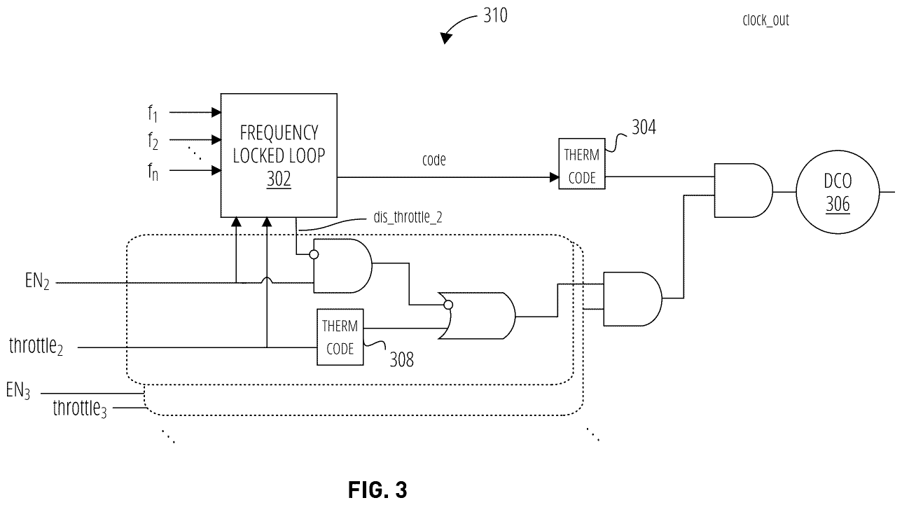

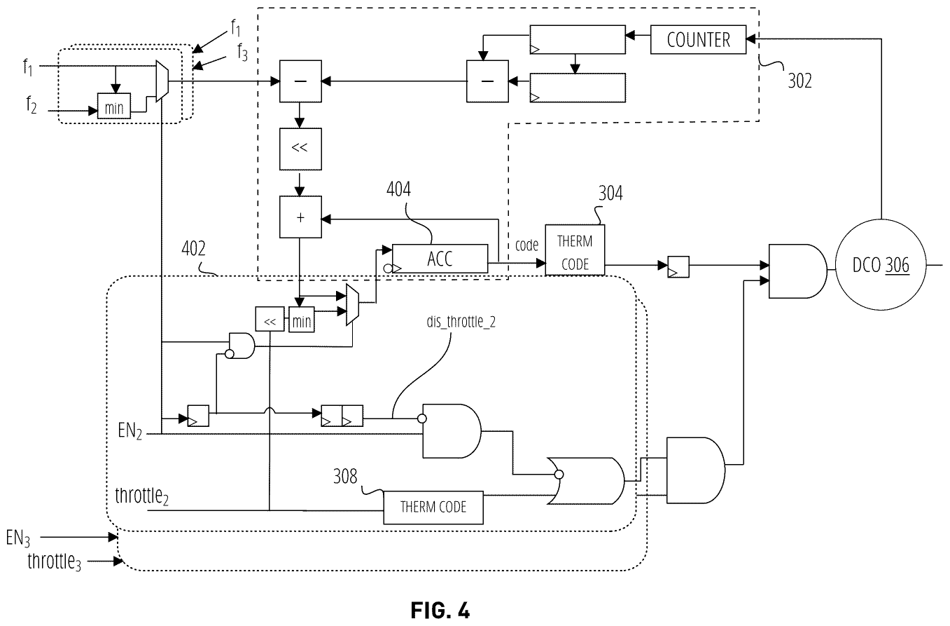

FIG. 3 and FIG. 4 depict aspects of an embodiment of a V-F switching circuit 310 that may exhibit decreased dithering, improved scalability, and/or decrease characterization effort over the conventional mechanism depicted in FIG. 1 and FIG. 2. The V-F switching circuit 310 comprises a frequency locked loop 302 that applies a code to a thermometer decoder 304 that in turn sets the output clock CLOCK_OUT of a digitally controlled oscillator 306. A stage comprising a thermometer decoder 308 is provided for each of the V-F switching domains (f₂ . . . fₙ) of an integrated circuit for which clock throttling may be applied.

The frequency locked loop 302 differs from the conventional design depicted in FIG. 2 in some aspects, and may comprise various logic that is depicted in FIG. 2 with familiar functional symbols such as subtraction circuits (“−”), addition circuits (“+”), an accumulator 404, flops (boxes comprising a triangular clock input), selection circuits, e.g., muxes (truncated triangle), shift circuits (“<<”), minimum selectors (“min”), and so on.

Unlike the frequency locked loop 104 in the conventional mechanism, the frequency locked loop 302 obviates use of a DROPCODE and auto-adjusts to changes in the selected V-F switching domain via the action of regulator 402. The obviation of DROPCODEs saves area as the number of V-F switching domains is increased, and unlike conventional mechanisms margining for different V-F switching states need not be cumulative. The throttle values applied at the various stages correspond to actual CLOCK_OUT values of the digitally controlled oscillator 306, not offset amounts to be applied to output codes of the frequency locked loop 302. In other words, the throttle code and the code each comprise complete output settings for the digitally controlled oscillator, not partial settings (e.g., offsets).

As part of a switch between V-F switching domains (e.g., f₁→f₂), the target domain is enabled (e.g., EN₂) and a throttle code corresponding to the target V-F switching domain (e.g., throttle₂) is applied directly via low-latency combinatorial logic to the digitally controlled oscillator 306, as opposed to subtracting the frequency locked loop 104 code from an offset value as in the conventional mechanism.

Upon assertion of EN₂, the throttle₂ code is rapidly applied to the digitally controlled oscillator 306 to effectuate a throttling of CLOCK_OUT. The frequency locked loop 302 reacts to EN₂ by reducing its output code to the setting of throttle₂ at which point the frequency locked loop 302 asserts dis_throttle_2, removing the application of throttle₂ from the digitally controlled oscillator 306 and restoring control over CLOCK_OUT to the frequency locked loop 302.

The stages each comprise a fast-propagation path for the throttle code to the digitally controlled oscillator 306, and the frequency locked loop 302 is configured to generate code to the digitally controlled oscillator 306 over a slow path and to disable the fast path to the digitally controlled oscillator 306 upon the code satisfying a match condition with the throttle code.

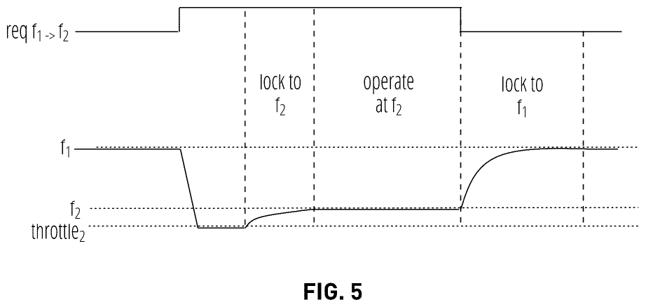

Referring to the example depicted in FIG. 5, once the throttle code is applied to the digitally controlled oscillator 306, control returns via the regulator 402 of the frequency locked loop 302 and the frequency locked loop 302 locks to the throttled target frequency (e.g., f₂). The application of an offset value as in the conventional mechanism is obviated. During a switch back from a throttled V-F switching domain to the default V-F switching domain (e.g., f₂→f₁), the frequency locked loop 302 converges to a lock from its current output frequency back to the default frequency.

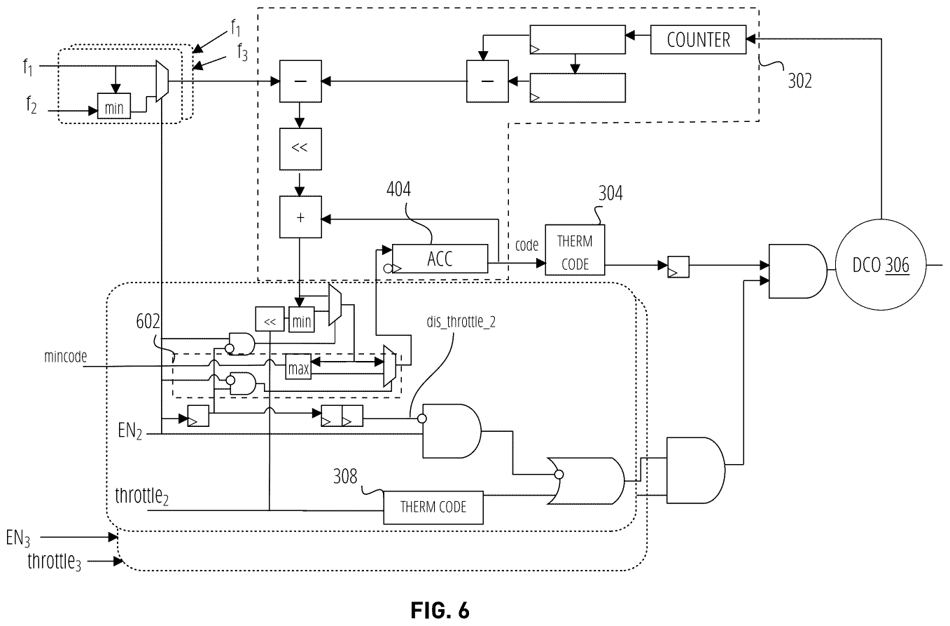

The embodiment described in conjunction with FIG. 6 re-locks the output clock to a slowest of any remaining active throttled frequency domains by way of an incremental settling (e.g., measure error, take a step, measure error, take a step . . . ) of the frequency locked loop 302 to the throttled frequency of that domain. This frequency locked loop 302 settling time may introduce latency and reduce performance of the clocked components in some situations.

The set of active throttled frequency domains is set based on the circuitry activated for a particular state of the integrated circuit, e.g., the circuitry utilized to calculate a particular applied workload.

FIG. 6 depicts an embodiment wherein upon exit from a throttled clock domain accelerates the setting of the output clock to the frequency the fastest domain that is safely available for the current or imminent state of the clocked circuits.

A mincode value may be pre-set with the next-highest frequency domain that is safe for operation. The mincode value encodes a maximum throttle code setting from among the currently active clock frequency domains that remain after disabling the current one. If there are no other active throttled clock frequency domains remaining, the mincode value encodes the default (highest) clock frequency domain setting.

The mincode may be applied to the digitally controlled oscillator 306 via a low-latency path upon exit from a current throttled clock domain. The low-latency application of the mincode to the digitally controlled oscillator 306 enables a rapid transition between frequency domains without requiring the frequency locked loop 302 to incrementally undergo many iterations to settle through the entire frequency distance between the domains.

Each stage (dotted lines) may comprise accelerator 602 logic that applies mincode to the accumulator 404 of the frequency locked loop 302 with low latency. The mincode is applied upon disabling a stage (e.g., toggling the enable signal EN for a stage from high to low) to effectuate a low-latency transition from a slower clock frequency to a fastest frequency that is also safe for the circuitry to operate in.

The frequency locked loop 302 reacts rapidly to the setting in the accumulator 404 by reducing its output code to match mincode and obviate the previous clock throttle setting.

The accelerator 602 selects the maximum of the applied mincode and the current code setting of the frequency locked loop 302. In the example depicted in FIG. 6, when the stage enable signal (EN₂) transitions from asserted to de-asserted, this maximum setting is selected for application to the frequency locked loop 302 for one clock cycle.

The mincode setting may be updated for example in response to exiting a frequency domain and disabling one of the throttle stages, by computing a minimum of any active throttle codes and default (highest frequency) code remaining after the disabling of the stage. Transient performance loss while transitioning between frequency domains may thereby be mitigated.

Consider an implementation of an integrated circuit may comprise three frequency domains: the default, highest frequency domain of operation, and two throttled frequency domains. By way of example, the default frequency domain may comprise a maximum frequency of 100 GHz and the two throttled frequency domains may comprise maximum frequencies of 90 GHz and 80 GHz. For a particular workload, all of these domains may be set to be active, in which case the integrated circuit will operate in the 80 GHz domain (the slowest of the active domains). Upon exiting the 80 GHz domain, the integrated circuit transitions to a 90 GHz operating state, the next frequency domain that is safe for the current workload state. This transition involves dropping (disabling) the enable signal for the the 80 GHz throttling stage, loading the accumulator 404 with the code for throttling to 90 GHz with low-latency (relative the the settling time of the frequency locked loop 302), and applying this code to the digitally controlled oscillator 306. The enable signal for the 90 GHz throttling stage may then be asserted.

This sets the digitally controlled oscillator 306 output to a frequency close to 90 GHz with low-latency, followed by an incremental lock of the frequency locked loop 302 to 90 GHz via it's internal feedback loop.

In some situations, an integrated circuit may be in an idle state due to their being no applied workload. Upon the application of a workload to the integrated circuit, the disclosed mechanisms may be utilized to rapidly bring the output of the digitally controlled oscillator 306 to the highest frequency that is safe for the applied workload. In general, the disclosed mechanisms may be utilized in any scenario where the operating conditions of an integrated circuit change and the integrated circuit transitions to operate at a higher frequency from a slower one.

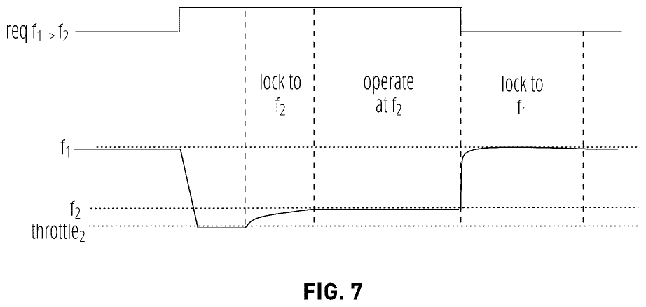

Referring to the example depicted in FIG. 7, upon exiting a throttled clock domain, and once the mincode is applied with low-latency to the accumulator 404, the digitally controlled oscillator 306 output jumps to the next-highest frequency of safe operation. Subsequently, control returns via the regulator 402 of the frequency locked loop 302 and the frequency locked loop 302 locks to the new throttled (or default) target frequency (e.g., f₂). The application of an offset value as in the conventional mechanism is obviated.

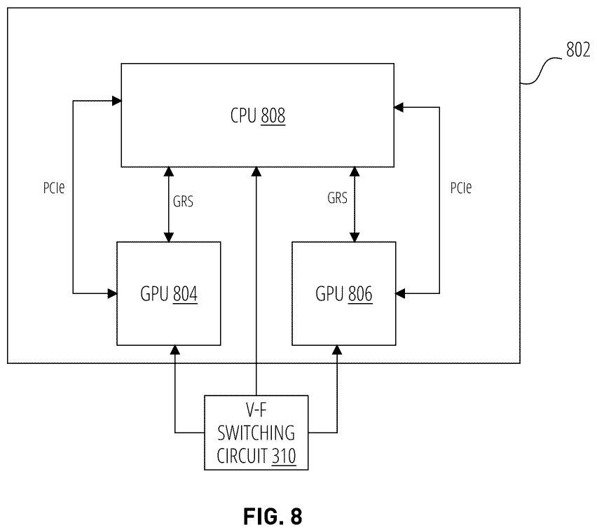

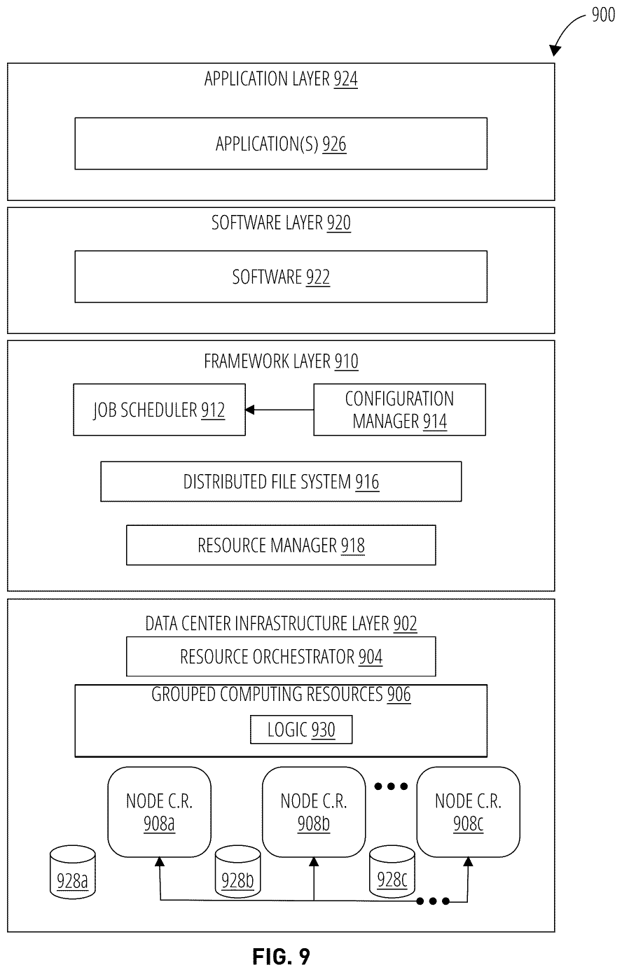

FIG. 8 depicts a processing device 802 that includes a central processing unit 808 and two (or more) graphics processing units 804, 806. The processing device 802 may in one embodiment be implemented on a single silicon die (i.e., a ‘superchip’) and may be utilized, often in large numbers, in a data center. An exemplary data center 900 that may utilize the processing device 802 is depicted in FIG. 9. As depicted in the example embodiment of FIG. 8, the central processing unit 808 may be coupled to the graphics processing units 804, 806 via a die-to-die (D2D) or chip-to-chip (C2C) interconnect such as a Ground-Referenced Signaling interconnect (GRS interconnect). The central processing unit 808 may be coupled to the graphics processing units 804, 806 via PCIe (Peripheral Component Interconnect Express) interconnects. One or more V-F switching circuit 310 may be utilized with the central processing unit 808 and the graphics processing units 804, 806 due to the the central processing unit 808 comprising a different V-F switching curve that the graphics processing units 804, 806.

FIG. 9 depicts an exemplary data center 900, in accordance with at least one embodiment. In at least one embodiment, data center 900 includes, without limitation, a data center infrastructure layer 902, a framework layer 910, a software layer 920, and an application layer 924.

In at least one embodiment, as depicted in FIG. 9, data center infrastructure layer 902 may include a resource orchestrator 904, grouped computing resources 906, and node computing resources (node C.R.s) 908a, 908b, 908c, where “N” represents any whole, positive integer. In at least one embodiment, node computing resources may include, but are not limited to, any number of central processing units (CPUs) or other processors (including accelerators, field programmable gate arrays (FPGAs), graphics processors, etc.), memory devices 928a, 928b, 928c (e.g., dynamic random-access memory, solid state or disk drives, etc.), network input/output (NW I/O) devices, network switches, virtual machines (VMs), power modules, and cooling modules, etc. In at least one embodiment, one or more node computing resources from among node computing resources 908a, 908b, 908c may be a server having one or more of the above-mentioned computing resources.

In at least one embodiment, grouped computing resources 906 may include separate groupings of node computing resources housed within one or more racks (not shown), or many racks housed in data centers at various geographical locations (also not shown). Separate groupings of node computing resources within grouped computing resources 906 may include grouped compute network, memory, or storage resources that may be configured or allocated to support one or more workloads. In at least one embodiment, several node computing resources including CPUs or processors may be grouped within one or more racks to provide compute resources to support one or more workloads. In at least one embodiment, one or more racks may also include any number of power modules, cooling modules, and network switches, in any combination.

In at least one embodiment, resource orchestrator 904 may configure or otherwise control one or more node computing resources 908a, 908b, 908c and/or grouped computing resources 906. In at least one embodiment, resource orchestrator 904 may include a software design infrastructure (“SDI”) management entity for data center 900. In at least one embodiment, resource orchestrator 904 may include hardware, software, or some combination thereof.

In at least one embodiment, as depicted in FIG. 9, framework layer 910 includes, without limitation, a job scheduler 912, a configuration manager 914, a resource manager 918, and a distributed file system 916. In at least one embodiment, framework layer 910 may include a framework to support software 922 of software layer 920 and/or one or more application(s) 926 of application layer 220. In at least one embodiment, software 922 or application(s) 926 may respectively include web-based service software or applications, such as those provided by Amazon Web Services, Google Cloud, and Microsoft Azure. In at least one embodiment, framework layer 910 may be, but is not limited to, a type of free and open-source software web application framework such as Apache SPARK™ (hereinafter “Spark) that may utilize a distributed file system 916 for large-scale data processing (e.g., “big data”). In at least one embodiment, job scheduler 912 may include a Spark driver to facilitate scheduling of workloads supported by various layers of data center 900. In at least one embodiment, configuration manager 914 may be capable of configuring different layers such as software layer 920 and framework layer 910, including Spark and distributed file system 916 for supporting large-scale data processing. In at least one embodiment, resource manager 918 may be capable of managing clustered or grouped computing resources mapped to or allocated for support of distributed file system 916 and job scheduler 912. In at least one embodiment, clustered or grouped computing resources may include grouped computing resources 906 at data center infrastructure layer 902. In at least one embodiment, resource manager 918 may coordinate with resource orchestrator 904 to manage these mapped or allocated computing resources.

In at least one embodiment, software 922 included in software layer 920 may include software used by at least portions of node computing resources 908a, 908b, 908c, grouped computing resources 906, and/or distributed file system 916 of framework layer 910. One or more types of software may include, but are not limited to, Internet web page search software, e-mail virus scan software, database software, and streaming video content software.

In at least one embodiment, application(s) 926 included in application layer 924 may include one or more types of applications used by at least portions of node computing resources 908a, 908b, 908c, grouped computing resources 906, and/or distributed file system 916 of framework layer 910. In at least one or more types of applications may include, without limitation, Compute Unified Device Architecture (CUDA) applications, 5G network applications, artificial intelligence applications, data center applications, and/or variations thereof. In at least one embodiment, one or more types of applications may include, but are not limited to, any number of a genomics application, a cognitive compute, application and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 914, resource manager 918, and resource orchestrator 904 may implement any number and type of self-modifying actions based on any amount and type of data acquired in any technically feasible fashion. In at least one embodiment, self-modifying actions may relieve a data center operator of data center 900 from making possibly bad configuration decisions and possibly avoiding underutilized and/or poorly performing portions of a data center.

In at least one embodiment, data center 900 may comprise tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to data center 900. In at least one embodiment, trained machine learning models corresponding to one or more neural networks may be used to infer or predict information using resources described above with respect to data center 900 by using weight parameters calculated through one or more training techniques described herein.

In at least one embodiment, data center 900 may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

The grouped computing resources 906 may be configured with logic 930 to implement the application(s) 926. For example, the logic 930 may comprise inference and/or training logic to perform deep learning inferencing and/or training operations associated with one or more embodiments. In at least one embodiment, logic 930 may configure the data center 900 for inferencing or predicting operations based, at least in part, on weight parameters calculated using neural network training operations, neural network functions and/or architectures, or neural network use cases described herein.

### LISTING OF DRAWING ELEMENTS

102 thermometer decoder
104 frequency locked loop
106 multiple-input digitally-controlled oscillator
202 minimum selector
302 frequency locked loop
304 thermometer decoder
306 digitally controlled oscillator
308 thermometer decoder
310 V-F switching circuit
402 regulator
404 accumulator
602 accelerator
802 processing device
804 graphics processing unit
806 graphics processing unit
808 central processing unit
900 data center
902 data center infrastructure layer
904 resource orchestrator
906 grouped computing resources
908a node computing resource
908b node computing resource
908c node computing resource
910 framework layer
912 job scheduler
914 configuration manager
916 distributed file system
918 resource manager
920 software layer
922 software
924 application layer
926 application(s)
928a memory device
928b memory device
928c memory device
930 logic

Various functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on. “Logic” refers to machine memory circuits and non-transitory machine readable media comprising machine-executable instructions (software and firmware), and/or circuitry (hardware) which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter). Logic symbols in the drawings should be understood to have their ordinary interpretation in the art in terms of functionality and various structures that may be utilized for their implementation, unless otherwise indicated.

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112(f) for that claim element. Accordingly, claims in this application that do not otherwise include the “means for” [performing a function] construct should not be interpreted under 35 U.S.C § 112(f).

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

As used herein, the phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

As used herein, the terms “first,” “second,” etc. are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

Although the terms “step” and/or “block” may be used herein to connote different elements of methods employed, the terms should not be interpreted as implying any particular order among or between various steps herein disclosed unless and except when the order of individual steps is explicitly described.

Having thus described illustrative embodiments in detail, it will be apparent that modifications and variations are possible without departing from the scope of the intended invention as claimed. The scope of inventive subject matter is not limited to the depicted embodiments but is rather set forth in the following Claims.

What is claimed is:

1. A circuit comprising:
a first fast-propagation path configured to propagate a first code from a plurality of stages to a digitally controlled oscillator;
a frequency locked loop configured to (a) generate a second code to the digitally controlled oscillator over a slow-propagation path, and (2) disable the first fast-propagation path to the digitally controlled oscillator upon the first code satisfying a match with the second code; and
a second fast-propagation path configured to propagate a second code to the digitally controlled oscillator.

2. The circuit of claim 1, wherein the second code comprises a determined maximum frequency code from among a plurality of active frequency codes.

3. The circuit of claim 1, further comprising:
the second fast-propagation path configured to propagate the second code to the digitally controlled oscillator in response to disabling a currently enabled one of the stages.

4. The circuit of claim 1, wherein the first code comprises a frequency throttle code.

5. The circuit of claim 1, wherein the second code and the first code each comprise complete output settings for the digitally controlled oscillator.

6. The circuit of claim 1, further configured such that the fast-propagation path to the digitally controlled oscillator is disabled upon the frequency locked loop locking on a frequency corresponding to the first code.

7. The circuit of claim 1, wherein the frequency locked loop comprises a regulator configured to determine when the second code satisfies the match with the first code.

8. The circuit of claim 1, wherein:
each stage is configured to receive an enable signal for a respective first code; and
the frequency locked loop is configured to revert to generating a default code upon de-assertion of the enable signals to the stages.

9. A system comprising:
a first circuit comprising a first voltage/frequency switching characteristic;
a second circuit comprising a second voltage/frequency switching characteristic;
a voltage/frequency domain switching circuit coupled to the first circuit and to the second circuit, the voltage/frequency domain switching circuit comprising:
a first fast-propagation path configured to propagate a throttle code from a plurality of inputs to a digitally controlled oscillator;
a frequency locked loop configured to (a) generate a code to the digitally controlled oscillator over a slow-propagation path, and (2) disable the fast-propagation path to the digitally controlled oscillator upon the code satisfying a match with the throttle code; and
a second fast-propagation path configured to propagate a second code to the digitally controlled oscillator.

10. The system of claim 9, wherein the second code comprises one of (a) a determined maximum throttle code from among a plurality of active throttle codes, or (b) an unthrottled frequency code.

11. The system of claim 9, the second fast-propagation path configured to propagate the second code to the digitally controlled oscillator in response to disabling a currently enabled frequency domain for either the first voltage/frequency switching characteristic or the second voltage/frequency switching characteristic.

12. The system of claim 9, wherein the first circuit is a central processing unit and the second circuit is a graphics processing unit.

13. The system of claim 9, wherein the throttle code and the code each comprise complete output settings for the digitally controlled oscillator.

14. The system of claim 9, further configured such that the fast-propagation path to the digitally controlled oscillator is disabled upon the frequency locked loop locking on a frequency corresponding to the throttle code.

15. The system of claim 9, wherein the frequency locked loop comprises a regulator configured to determine when the code generated by the frequency locked loop satisfies the match with the throttle code.

16. The system of claim 9, wherein:
each input is configured to receive an enable signal for a respective throttle code; and
the frequency locked loop is configured to revert to generating a default code upon de-assertion of the enable signals to the inputs.

17. A data center comprising:
a central processing unit comprising a first voltage/frequency switching characteristic;
a graphics processing unit comprising a second voltage/frequency switching characteristic;
a voltage/frequency domain switching circuit coupled to the central processing unit and to the graphics processing unit, the voltage/frequency domain switching circuit comprising:
a first fast-propagation path for propagating plurality of first codes to a digitally controlled oscillator;
a frequency locked loop configured to (a) generate a second code to the digitally controlled oscillator over a slow-propagation path, and (2) disable the first fast-propagation path to the digitally controlled oscillator upon the second code satisfying a match with one of the first codes; and
a second fast-propagation path configured to propagate a second code to the digitally controlled oscillator.

18. The data center of claim 17, wherein the second code comprises one of (a) a determined maximum throttle code from among a plurality of active throttle codes, or (b) an unthrottled frequency code.

19. The data center of claim 17, the second fast-propagation path configured to propagate the second code to the digitally controlled oscillator in response to disabling a currently enabled frequency domain for either the central processing unit or the graphics processing unit.

20. The data center of claim 17, wherein the first codes are different frequency throttle codes.

21. The data center of claim 17, wherein the first processor is a central processing unit and the second processor is a graphics processing unit.

22. The data center of claim 17, wherein the first codes and the second code each comprise complete output settings for the digitally controlled oscillator.

23. The data center of claim 17, further configured such that the fast-propagation path to the digitally controlled oscillator is disabled upon the frequency locked loop locking on a frequency corresponding to one of the first codes.

24. The data center of claim 17, wherein the frequency locked loop comprises a regulator configured to determine when the second code generated by the frequency locked loop satisfies the match with one of the first codes.

25. The data center of claim 17, wherein:
each input is configured to receive an enable signal for a respective first code; and
the frequency locked loop is configured to revert to generating a default code upon de-assertion of the enable signals to the inputs.

26. A supply voltage control process comprising:
transmitting, over a fast-propagation path, frequency throttle codes from a plurality of input stages to a digitally controlled oscillator; and
operating a frequency locked loop to (a) generate a control code to the digitally controlled oscillator over a slow-propagation path, and (2) disable the fast-propagation path to the digitally controlled oscillator upon one of the frequency throttle codes satisfying a match with the control code.
